(19) United States
(12) Patent Application Publication
(10) Pub. No.: US 2025/0379054 A1
(43) Pub. Date: Dec. 11, 2025

(54) METHOD OF FORMING HARD MASK STRUCTURE

(71) Applicant: Tokyo Electron Limited, Tokyo (JP)

(72) Inventors: Joshua Baillargeon, Albany, NY (US); Jeffrey Shearer, Albany, NY (US)

(21) Appl. No.: 18/771,873

(22) Filed: Jul. 12, 2024

Related U.S. Application Data
(63) Continuation-in-part of application No. 18/734,683, filed on Jun. 5, 2024.

(51) Int. Cl. H01L 21/033; H01L 21/311

(52) U.S. Cl. CPC H01L 21/0337; H01L 21/31144

(57) ABSTRACT

A method for forming a semiconductor device can include forming a metal mask layer on a substrate, where the metal mask layer contains tungsten, and forming a patterned mask directly on the metal mask layer, where the forming of the patterned mask includes forming a barrier layer directly on the metal mask layer, where the barrier layer contains nitrogen, forming a dielectric layer directly on the barrier layer, where the dielectric layer contains oxygen, and patterning and etching the dielectric layer and the barrier layer to form holes through the dielectric layer and the barrier layer, such that the holes open to the metal mask layer.

### CROSS-REFERENCE TO RELATED APPLICATIONS

This application is a continuation-in-part of and claims priority to U.S. patent application Ser. No. 18/734,683 filed on Jun. 5, 2024, which application is hereby incorporated herein by reference in its entirety.

### TECHNICAL FIELD

The present disclosure relates generally to methods for manufacturing semiconductor devices, and more particularly, processes of forming a hard mask structure for manufacturing semiconductor devices.

### BACKGROUND

Various layers and materials have been used for hard mask structures, which can be used for forming structures and features such as capacitors for dynamic random access memory (DRAM) devices. Typically, before a high aspect ratio feature, such as a high aspect ratio contact (HARC), can be etched and formed in a semiconductor material, a hard mask structure is first formed and patterned to form a metal hard mask over semiconductor materials of a substrate.

A metal hard mask is typically more resistant to etchants used for etching the underlying semiconductor materials. The enhanced etch selectivity allows for the metal hard mask to provide controlled and precise patterning while etching the underlying semiconductor materials. Additionally, this can provide better control over critical dimensions, especially when forming high aspect ratio features that require high precision.

The material for a metal hard mask structure is typically selected based on its compatibility with the later semiconductor processing steps when using the metal hard mask to pattern and etch the underlying semiconductor materials, such as etch chemicals, temperature, plasma, and ion bombardment (e.g., during reactive ion etching or RIE). A metal hard mask can endure the semiconductor processing conditions while maintaining its critical dimensions and sufficient thickness for reaching high aspect ratios while etching the underlying semiconductor materials through the hard mask structure.

And because the metal hard mask is the mask for forming semiconductor structures and patterns, the critical dimensions obtained during the formation of the metal hard mask require precision and uniformity for achieving high-quality and smaller scaled dimensions (i.e., greater device density) for the semiconductor device being made. As size and geometry scaling continues to shrink in semiconductor devices, new materials are tested and developed for metal hard masks, as well as new etching chemistries and conditions for new and currently-used metal hard mask materials and/or new or currently-used etching equipment. And as size and geometry continue to scale to smaller dimensions and/or deeper contacts for the semiconductor devices, new etching chemistries and processes are needed to allow for target critical dimensions and pattern uniformity to be achieved while making a metal hard mask. Also, different hard mask structures, which include a layer or layers that will become the patterned metal hard mask, are needed to pattern and etch the metal hard mask based on the combination and selection of metal hard mask material(s), etch chemistries, and etch processes to better achieve the specifications and critical dimensions for the patterned metal hard mask.

### SUMMARY

In accordance with an embodiment of the present disclosure, a method for forming a semiconductor device can include: forming a metal mask layer on a substrate, where the metal mask layer contains tungsten; and forming a patterned mask directly on the metal mask layer, where the forming of the patterned mask includes forming a barrier layer directly on the metal mask layer, where the barrier layer contains nitrogen, forming a dielectric layer directly on the barrier layer, where the dielectric layer contains oxygen, and patterning and etching the dielectric layer and the barrier layer to form holes through the dielectric layer and the barrier layer, such that the holes open to the metal mask layer.

In accordance with an embodiment of the present disclosure, a method for forming a semiconductor device can include: providing a substrate having a first barrier layer as a top-most layer of the substrate, where the first barrier layer contains nitrogen; forming a metal mask layer directly on the first barrier layer, where the metal mask layer contains tungsten and where the metal mask layer contains silicon, nitrogen, or a combination of silicon and nitrogen; and forming a patterned mask directly on the metal mask layer, where the forming of the patterned mask includes forming a second barrier layer directly on the metal mask layer, where the second barrier layer contains nitrogen, forming a first dielectric layer directly on the second barrier layer, where the first dielectric layer contains oxygen, and patterning and etching the first dielectric layer and the second barrier layer to form holes through the first dielectric layer and the second barrier layer, such that the holes open to the metal mask layer.

In accordance with an embodiment of the present disclosure, a method for forming a semiconductor device can include: providing a substrate having a first barrier layer as a top-most layer of the substrate, where the first barrier layer includes silicon nitride; forming a metal mask layer directly on the first barrier layer, where the metal mask layer contains tungsten; and forming a patterned mask directly on the metal mask layer, where the forming of the patterned mask includes forming a second barrier layer directly on the metal mask layer, where the second barrier layer includes silicon nitride, forming a third barrier layer directly on the second barrier layer, where the third barrier layer includes silicon oxynitride, forming a first dielectric layer directly on the third barrier layer, where the first dielectric layer includes silicon dioxide, and patterning and etching the first dielectric layer, the third barrier layer, and the second barrier layer to form holes through the first dielectric layer, the third barrier layer, and the second barrier layer, such that the holes open to the metal mask layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1-5 are cross-section views illustrating intermediate structures of a semiconductor device made using a method according to an embodiment of the present disclosure;

FIG. 6 is a top view of a mask structure made according to some embodiments of the present disclosure;

FIG. 7 is cross-section view illustrating an intermediate structure of a semiconductor device made using a method according to an embodiment of the present disclosure;

FIGS. 8-10 are cross-section views illustrating intermediate structures of a semiconductor device made using a method according to an embodiment of the present disclosure;

FIG. 11 is cross-section view illustrating an intermediate structure of a semiconductor device made using a method according to an embodiment of the present disclosure;

FIG. 12 illustrates a flow chart implementing the forming of a mask structure in accordance with an embodiment of the present disclosure;

FIG. 13 illustrates a flow chart implementing the forming of a semiconductor device in accordance with an embodiment of the present disclosure; and

FIG. 14 illustrates a flow chart implementing the forming of a semiconductor device in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure, certain elements may be discussed, referred to, and actually plural, but only shown as a singular example in the drawings, even though that single example is among a set of a plurality. Similarly, certain elements may be discussed, referred to, and shown as singular, but may be plural or may be part of a set of a plurality of the same. Given that a structure and feature is typically repeated many times in a semiconductor device, one of ordinary skill in the art to which the present disclosure pertains can realize and understand such alternating between singular and plural.

For a metal hard mask structure, during the formation of a metal mask layer and/or during the formation of subsequent layers of a first mask layer over the metal mask layer, the metal mask layer can be oxidized or oxygen can migrate into the metal mask layer, which can be undesirable for some process flow integrations. For example, oxygen from an underlying layer of the substrate and/or oxygen from an overlying layer can migrate into the metal mask layer due to high temperatures (e.g., more than 400° C.) during the formation of overlying layers. Thus, there is a need to protect the metal mask layer from being oxidized in this way.

In some embodiments of the present disclosure, a method for forming a semiconductor device can include: forming a metal mask layer on a substrate, where the metal mask layer contains tungsten, contains tungsten and silicon, contains tungsten and nitrogen, or contains tungsten, silicon, and nitrogen; and forming a patterned mask directly on the metal mask layer, where the forming of the patterned mask includes forming a barrier layer directly on the metal mask layer, where the barrier layer contains nitrogen, forming a dielectric layer directly on the barrier layer, where the dielectric layer contains oxygen, and patterning and etching the dielectric layer and the barrier layer to form holes through the dielectric layer and the barrier layer, such that the holes open to the metal mask layer.

In some embodiments of the present disclosure, a method for forming a semiconductor device can include: providing a substrate having a first barrier layer as a top-most layer of the substrate, where the first barrier layer includes silicon nitride and/or silicon oxynitride; forming a metal mask layer directly on the first barrier layer, where the metal mask layer contains tungsten, contains tungsten and silicon, contains tungsten and nitrogen, or contains tungsten, silicon, and nitrogen; and forming a patterned mask directly on the metal mask layer, where the forming of the patterned mask includes forming a second barrier layer directly on the metal mask layer, where the second barrier layer includes silicon nitride, forming a third barrier layer directly on the second barrier layer, where the third barrier layer includes silicon oxynitride, forming a first dielectric layer directly on the third barrier layer, where the first dielectric layer includes silicon dioxide, and patterning and etching the first dielectric layer, the third barrier layer, and the second barrier layer to form holes through the first dielectric layer, the third barrier layer, and the second barrier layer, such that the holes open to the metal mask layer.

In some embodiment of the present disclosure, the method further includes: etching in the holes to increase hole depths of the holes into the metal mask layer such that the holes extend through the metal mask layer and open to the first barrier layer; removing the first dielectric layer and the second/third barrier layer(s); and etching the first barrier layer and the substrate via the holes to extend the holes into the substrate. Some example embodiments of the present disclosure are described below. Other embodiments can also be understood from the entirety of the specification as well as the claims filed herein.

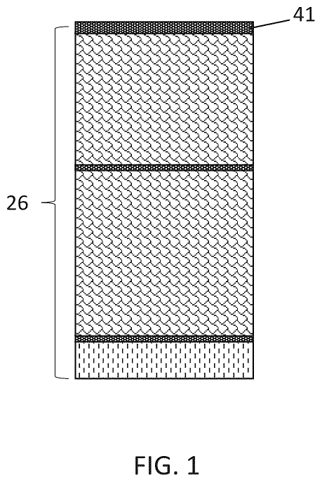

For simplification and illustration purposes, FIGS. 1 to 11 are merely showing some portions of a substrate and of intermediate structures for a semiconductor device that can be relevant to a method of making a semiconductor device according to some embodiments of the present disclosure. Accordingly, in FIGS. 1 to 11, to simplify the drawings, as can be readily understood by one of ordinary skill in the pertinent art, additional layers and structures for a semiconductor device made before, under, below, or adjacent the intermediate structures shown in the drawings can be omitted and not shown. And accordingly, in FIGS. 1 to 11, to simplify the drawings, as can be readily understood by one of ordinary skill in the pertinent art, additional layers and structures for a semiconductor device made after, over, above, or adjacent the intermediate structures shown in the drawings can be omitted and not shown. Furthermore, in an actual completed semiconductor device cross-section, the intermediate structures, or remnants thereof, that are illustrated and represented in the drawings of the present disclosure in a simplified manner as having squared edges, rectangular block shapes, and/or linear shapes can be actually pointed (e.g., bottoms of the holes), more rounded, more curved shaped, and less linear shaped (e.g., scalloped).

FIGS. 1 to 11 are various views of various intermediate structures of example semiconductor devices, schematically showing a processing sequence for forming the intermediate structures of the example semiconductor devices using methods according to some embodiments of the present disclosure. In FIGS. 1 to 11, the example semiconductor devices being built include holes 20 being formed in a metal mask layer 22 of a metal hard mask structure 24 for making capacitors for dynamic random access memory (DRAM) in the substrate 26. However, some embodiments of the present disclosure can be applied to making other types or portions of intermediate structures for other types and kinds of semiconductor devices.

Referring to FIG. 1, an intermediate structure can include a substrate 26 having a first barrier layer 41 formed over other layers that can vary per design and device being built. The substrate 26 can be a semiconductor material or a combination of semiconductor materials, such as silicon nitride (SiN), silicon dioxide (SiO₂), silicon, silicon germanium, silicon carbide, or any combination thereof, for example. The substrate 26 can be part of any suitable wafer type or structure, including a silicon wafer or a silicon-on-insulator (SOI) wafer, for example.

Even though the first barrier layer 41 is illustrated and represented in the drawings as a single layer of one material, in some embodiments, this first barrier layer 41 can be a single layer of one material, a single layer of a mix of multiple materials, multiple layers of one material, multiple layers of a same material or mix of multiple materials, or multiple layers of different materials, for example. In some embodiments, the material(s) of a given first barrier layer 41 can be selected in view of providing a barrier to oxygen migration from other layers of the substrate 26 into the metal mask layer 22, as well as providing acceptable etch selectivity with respect to etching of the metal mask layer 22, and fitting within the process integration flow and device electrical characteristics (e.g., etch selectivity, etch characteristics, thermal budgets, stress inducing, non-stress inducing, thermal stress mismatching, adhesion between vertically adjacent layer(s), etc.). In some embodiments, such material(s) of a given first barrier layer 41 can include nitride-containing material, such as silicon nitride (SiN), silicon oxynitride (SiON), silicon carbonitride (SiCN), silicon oxycarbonitride (SiOCN), layers thereof, mixtures thereof, laminates thereof, or generally any combination thereof, for example.

The thickness of the first barrier layer 41 can depend on the process flow integration. For example, the first barrier layer 41 can have a thickness in a range of 10 nm to 100 nm. At a minimum, the first barrier layer 41 can have a thickness sufficient to act as a barrier for the migration of oxygen from the substrate 26 into the metal mask layer 22. In some embodiments, the first barrier layer 41 can be formed using physical vapor deposition (PVD), chemical vapor deposition (CVD), plasma-enhanced chemical vapor deposition (PECVD), atomic layer deposition (ALD), plasma-enhanced atomic layer deposition (PEALD), or any combination thereof, for example. In some embodiments, the first barrier layer 41 can be a silicon nitride film formed using PECVD with a thickness in a range of 10 nm to 100 nm, for example.

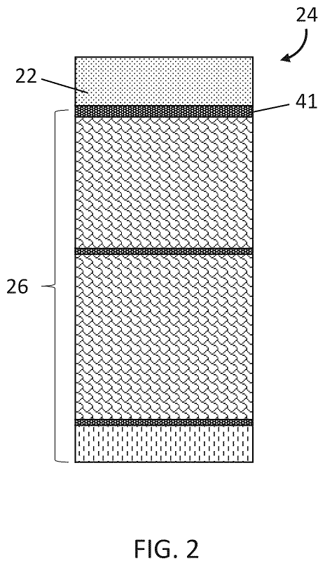

Referring to FIG. 2, the metal mask layer 22 can be formed on the substrate 26. In some embodiments, the metal mask layer 22 can be formed directly on the first barrier layer 41 of the substrate 26. In some embodiments, the metal mask layer 22 can contain tungsten and silicon, such as a tungsten silicide. In some embodiments, the metal mask layer 22 can contain tungsten, silicon, and nitrogen, such as W(Si)N. In some embodiments, the metal mask layer 22 can contain tungsten and nitrogen, such as WₓN.

Even though the metal mask layer 22 is illustrated and represented in the drawings as a single layer of one material, in some embodiments, the metal mask layer 22 can be a single layer of one material, a single layer of an alloy or mix of multiple materials, multiple layers of one material, multiple layers of a same alloy or mix of multiple materials, multiple layers of different materials or alloy(s) of materials, or a gradient of different materials within a film from top to bottom using multiple depositions, for example. In some embodiments, the metal mask layer 22 can be formed using PVD, CVD, PECVD, ALD, PEALD, or any combination thereof, for example. In some embodiments, the metal mask layer 22 can be W(Si)N formed using PVD at room temperature, for example.

In some embodiments, the metal mask layer 22 can contain 55-70% tungsten, in terms of atomic percentages for atomic composition. In some embodiments, the metal mask layer 22 can contain 4-26% silicon, in terms of atomic percentages for atomic composition. In some embodiments, the metal mask layer 22 can contain 10-40% nitrogen, in terms of atomic percentages for atomic composition. In some embodiments, the metal mask layer 22 can contain 59-63% tungsten, 21-25% silicon, and 14-18% nitrogen, for example. In some embodiments, the metal mask layer 22 can contain 61-65% tungsten, 9-13% silicon, and 23-27% nitrogen, for example.

The metal mask layer 22 can have a thickness in a range of 100 nm to 900 nm, for example. A thickness of the metal mask layer 22 can depend on the depth of the holes that are specified to be formed in the substrate using the metal mask layer 22, and the materials of the metal mask layer 22 and the substrate 26 (e.g., etch selectivity). For example, in some embodiments, the metal mask layer 22 can have a thickness in a range of 200 nm to 300 nm.

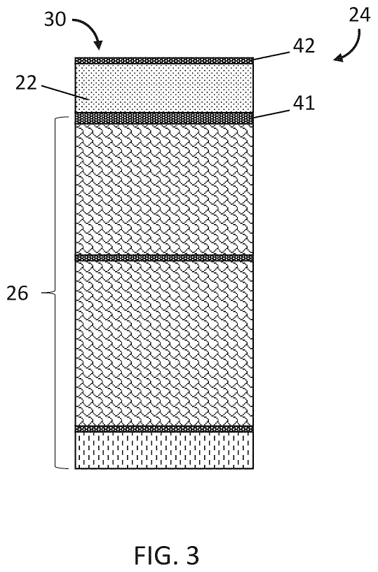

FIGS. 3-7 illustrate a series of intermediate structures for forming a first mask layer 30, which will be used to pattern and etch the metal mask layer 22. The first mask layer 30 can be a complex multilayered structure, as part of the overall metal hard mask structure 24. In other words, the metal hard mask structure 24 can include the first mask layer 30 and the metal mask layer 22.

Referring to FIG. 3, a second barrier layer 42 can be formed directly on the metal mask layer 22, as an initial layer of the first mask layer 30. Even though the second barrier layer 42 is illustrated and represented in the drawings as a single layer of one material, in some embodiments, this second barrier layer 42 can be a single layer of one material, a single layer of a mix of multiple materials, multiple layers of one material, multiple layers of a same material or mix of multiple materials, or multiple layers of different materials, for example. In some embodiments, the material(s) of a given second barrier layer 42 can be selected in view of providing a barrier to oxygen migration from other layers of the first mask layer 30 into the metal mask layer 22 and fitting within the process integration flow (e.g., etch selectivity, etch characteristics, thermal budgets, stress inducing, non-stress inducing, thermal stress mismatching, adhesion between vertically adjacent layer(s), etc.). In some embodiments, such material(s) of a given second barrier layer 42 can include nitride-containing material, such as silicon nitride (SiN), silicon oxynitride (SiON), silicon carbonitride (SiCN), silicon oxycarbonitride (SiOCN), layers thereof, mixtures thereof, laminates thereof, or generally any combination thereof, for example.

In some embodiments, the second barrier layer 42 can be formed using PVD, CVD, PECVD, ALD, PEALD, or any combination thereof, for example. In some embodiments, the second barrier layer 42 can be silicon nitride formed using PECVD with a thickness in a range of 5 nm to 50 nm, for example.

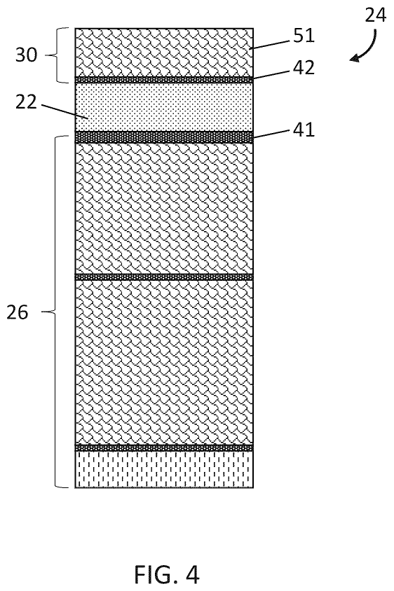

Referring to FIG. 4, a first oxygen-containing dielectric layer 51 can be formed directly on the second barrier layer 42, as part of the first mask layer 30. Even though the first dielectric layer 51 is illustrated and represented in the drawings as a single layer of one material, in some embodiments, the first dielectric layer 51 can be a single layer of one material, a single layer of a mix of multiple materials, multiple layers of one material, multiple layers of a same material or mix of multiple materials, or multiple layers of different materials, for example. In some embodiments, the material(s) of a given first dielectric layer 51 can be selected in view of providing acceptable etch selectivity relative to the metal mask layer 22 and fitting within the process integration flow (e.g., etch characteristics, thermal budgets, stress inducing, non-stress inducing, thermal stress mismatching, adhesion, etc.). In some embodiments, such material(s) of a given first dielectric layer 51 can be any suitable oxygen-containing material, such as silicon dioxide (SiO₂) (e.g., tetraethylorthosilicate (TEOS)) and structural variations thereof (e.g., flowable oxide, gel, including large air pockets, porous, etc.), composition/structural varying layers thereof, mixtures thereof, laminates thereof, or generally any combination thereof, for example.

In some embodiments, the first dielectric layer can be formed using PVD, CVD, PECVD, ALD, PEALD, or any combination thereof, for example. In some embodiments, the first dielectric layer 51 can be TEOS formed using PECVD with a thickness in a range of 10 nm to 300 nm, for example.

In some embodiments, the combination thickness of the second barrier layer 42 and the first dielectric layer 51 can be selected based on the resulting etch selectivity of the combination relative to the metal mask layer 22, with a thickness sufficient to etch holes 20 through the metal mask layer 22, which also depends on the etching and passivation chemistries used for forming holes through the metal mask layer. For example, while using an oxygen containing plasma for both the etching and passivation operations in forming holes 20 in a metal mask layer 22 made of WSi or W(Si)N, TEOS in the first dielectric layer 51 can have an etch selectivity of about 6.3 and SiN in the second barrier layer 42 can have an etch selectivity of about 4, relative to the etching rate for the metal mask layer 22. However, for other etching and passivation chemistries and/or for other material compositions of the metal mask layer 22, the etch selectivity can vary for the first dielectric layer 51 and the second barrier layer 42 relative to the metal mask layer 22. For a given embodiment, a thickness of the first dielectric layer 51 and the second barrier layer 42 can vary according to a variety of parameters, including: etch chemistry, passivation chemistry, hole diameter, depth-to-width aspect ratio of the holes, material composition of the metal mask layer, thickness of the metal mask layer, or any combination thereof, for example.

In some embodiments, a first dielectric layer 51 made from TEOS can have a thickness in a range of 250 nm to 300 nm, and a second barrier layer 42 made from SiN can have a thickness in a range of 5 nm to 50 nm, for example.

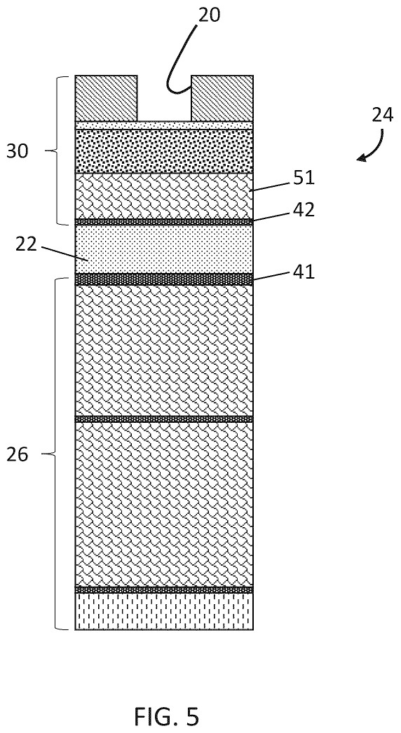

Referring to FIG. 5, additional layers may be formed over the first dielectric layer 51 to complete the stack of layers for the first mask layer 30. These additional layers can include any suitable lithography and masking layers, such as one or more of an organic material layer (e.g., diamond-like carbon, amorphous carbon layer (ACL)), an anti-reflective coating, a photolithography layer, or any combination thereof, for example.

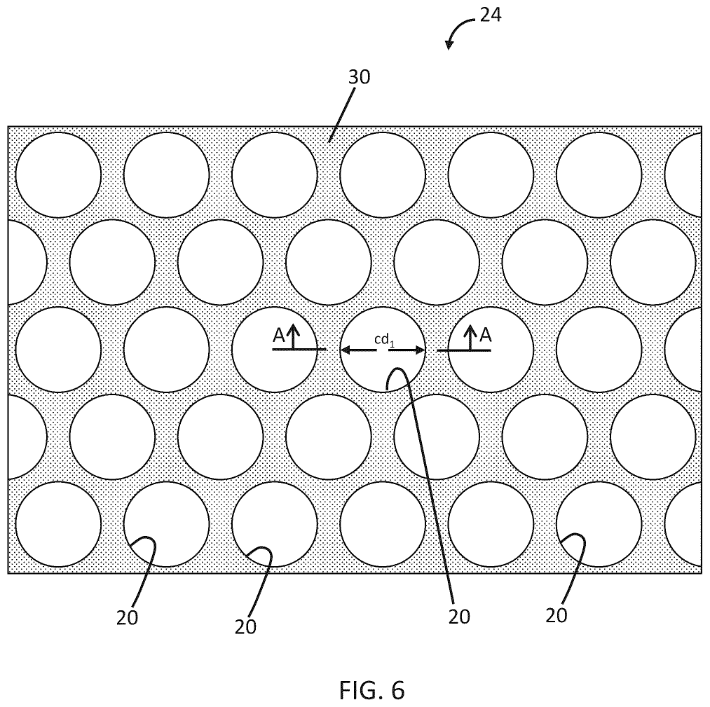

Still referring to FIG. 5, a hole 20 has been printed using lithography and is used to pattern the first mask layer 30. Referring to FIG. 6, a top view of the metal hard mask structure 24 of FIG. 5 is illustrated. FIG. 5 is an enlarged cross-section view taken along line A-A in FIG. 6. Referring to FIG. 6, the holes 20 can be arranged in a honeycomb or hexagon pattern, for example, which is typically used to allow for greater density and holes per area, and of which can lead to the formation of high aspect ratio contacts for capacitors of DRAM devices, for example. For example, in some embodiments, the holes 20 can have with a diameter (cd₁) of 20 nm and a center-to-center spacing between two adjacent holes of 40 nm. In some embodiments, the holes 20 of the patterning layers 22 and 30 can extend to a depth of more than 300 nm, for example. In other embodiments (not shown), the holes can be arranged in a square or grid pattern, for example. For simplification, only one hole 20 is shown in FIGS. 5 and 7-11. One of ordinary skill in the art can understand that in an actual semiconductor device, such metal hard mask structure 24 can have many more holes and/or patterned features (not shown).

The minimum dimension of patterned features can be shrunk periodically to roughly double the component density at each successive technology node, thereby reducing the cost per function. Innovations in patterning, such as immersion deep ultraviolet (i-DUV) lithography, multiple patterning and 13.5 nm wavelength extreme ultraviolet (EUV) optical systems have brought some critical dimensions down a scale less than ten nanometers. The holes 20 shown in FIGS. 5 and 6 can be formed using EUV, for example.

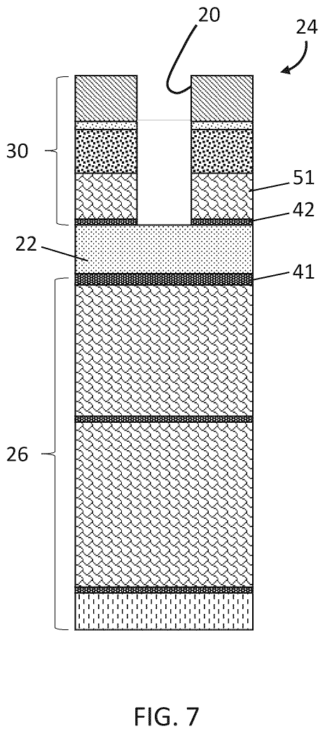

Referring to FIG. 7, the hole 20 can be etched through the first dielectric layer 51 and the second barrier layer 42, using the initial holes pattern formed in the upper layers of the first mask layer 30 (e.g., photolithography layer(s), anti-reflective layer(s), organic material layer(s)), until the hole 20 opens to the metal mask layer 22.

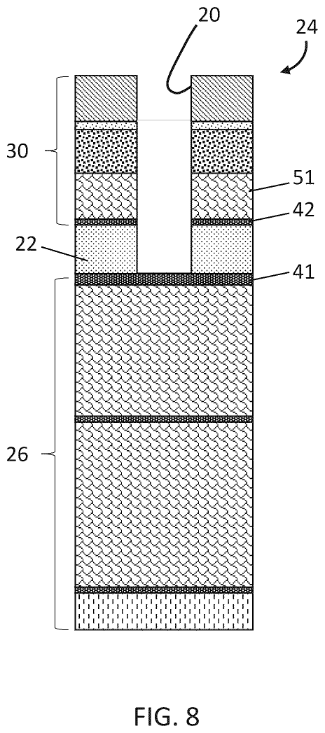

Referring to FIG. 8, the hole 20 can be extended into and through the metal mask layer 22 until the hole 20 opens to the first barrier layer 41. The first barrier layer 41 can have an etch selectivity relative to the metal mask layer 22. For example, for a given etch/passivation chemistry/process, the metal mask layer 22 can be etched at a rate about four to six times faster than the first barrier layer 41, which can help to fully open and develop the hole 20 in a more cylindrical pattern (e.g., less tapered, more vertical), and which can provide an etch stop function. The goal can be to form cylindrical shaped holes 20 (see e.g., FIG. 6) with mostly straight vertical sidewalls in the metal mask layer 22, such that the diameter and circular uniformity of each hole at the interface of the metal mask layer 22 and the first barrier layer 41 is as close as possible to the diameter (cd,) and circular uniformity of the holes formed in the first mask layer 30. Also, a goal can be to have uniformity and consistent diameters and circular shapes for many holes across the wafer.

After forming and patterning the first mask layer 30 of the metal hard mask structure 24, as illustrated in FIGS. 1-7 for example, the metal mask layer 22 can be patterned and etched using any suitable process. For example, in an embodiment of the present disclosure, after forming and patterning the first mask layer 30 of the metal hard mask structure 24, the metal mask layer 22 can be patterned and etched using a method embodiment disclosed and described in U.S. patent application Ser. No. 18/734,683 filed on Jun. 5, 2024, the entire contents of which are incorporated here by reference. While making an actual metal hard mask structure for making an actual semiconductor device, there can be many more operations in the sequence, and accordingly many intermediate structures in the sequence between FIG. 7 and FIG. 8. Thus, some operations of the overall sequence can be omitted to simplify the drawings, as can be apparent to one of ordinary skill in art to which the present disclosure pertains.

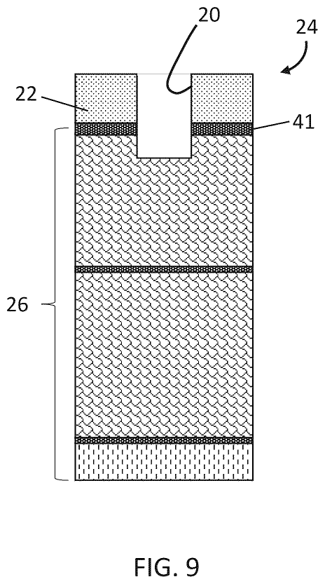

Referring to FIG. 9, the first mask layer 30, including the first dielectric layer 51 and the second barrier layer 42, can be removed (e.g., because the hole 20 is sufficiently patterned and etched in the metal mask layer 22). By removing the first mask layer 30, the aspect ratio (diameter to depth ratio) of the hole 20 can be reduced, which can aid in improving subsequent etching operations using the metal mask layer 22 for the pattern. Also, removing the first mask layer 30 can reduce or avoid oxidation and/or passivation of the metal mask layer 22 by materials from the first mask layer 30. As can be apparent to one of ordinary skill in the art, there can be many intermediate structures in the sequence between FIG. 8 and FIG. 9.

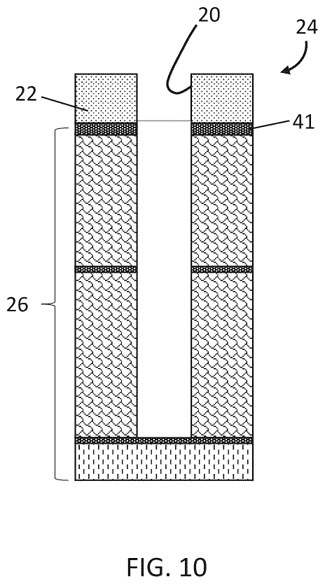

Referring to FIG. 10, the first barrier layer 41 and other layers of the substrate 26 can be etched via the hole 20 in the metal mask layer 22, to extend the hole 20 into the substrate 26. While etching the substrate 26 via the hole 20 using the metal mask layer 22 as the pattern for making an actual semiconductor device, there can be many operations in the sequence and/or overlapping and/or repeating, and accordingly there can be many intermediate structures in the sequence between FIG. 9 and FIG. 10. Thus, some operations of the overall sequence can be omitted to simplify the drawings, as can be apparent to one of ordinary skill in art to which the present disclosure pertains.

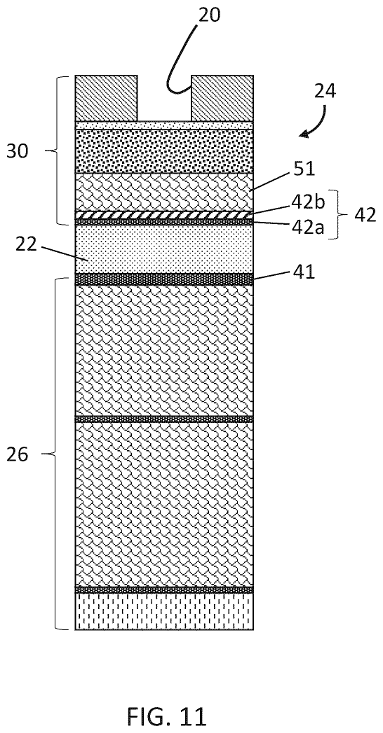

FIG. 11 is a cross-section view of an intermediate structure of a semiconductor device made using a method according to an embodiment of the present disclosure. Referring to FIG. 11, the second barrier layer 42 can include two layers 42a and 42b of different materials. For example, the second barrier layer 42 can include a first sub-layer 42a made of silicon nitride (SiN) and second sub-layer 42b made of silicon oxynitride (SiON). For implementing the intermediate structure of FIG. 11, the operations for an example method embodiment of the present disclosure can include those operations and structures illustrated and described above regarding FIGS. 1-10, except that the second barrier layer 42 includes two layers 42a and 42b of different materials as illustrated in FIG. 11, for example.

In some embodiments, a first sub-layer 42a made of silicon nitride, for example, can be deposited (e.g., with a thickness of 5-25 nm) directly on the metal mask layer 22, such that the first sub-layer 42a provides the primary function of a barrier for preventing or hindering oxygen migration into the metal mask layer 22 during the formation of other layers of the first mask layer 30. In some embodiments, after the first sub-layer 42a (e.g., SiN) is deposited directly on the metal mask layer 22, a second sub-layer 42b (which could also be considered as a third barrier layer, as alternative labeling) made of silicon oxynitride (SiON), for example, can be deposited (e.g., with a thickness of 10-50 nm) directly on the first sub-layer 42a. Accordingly, in some embodiments, after the second sub-layer 42b (e.g., SiON) is formed directly on the first sub-layer 42a, a first dielectric layer 51 (e.g., TEOS) can be deposited (e.g., with a thickness of 175-250 nm) directly on the second sub-layer 42b.

Similarly, in some embodiments of the present disclosure, the first barrier layer 41 can include a first sub-layer of SiON and a second sub-layer of SiN, such that the SiN layer is interposed between the SiON layer and the metal mask layer 22 and such that the metal mask layer 22 is deposited directly on the SiN layer. In such embodiments, the intermediate structures of FIGS. 1-11 can be the same except that the first barrier layer 41 includes two sub-layers. Also in such embodiments, the operations for an example method embodiment of the present disclosure can include those operations and structures illustrated and described above regarding FIGS. 1-10 and/or FIG. 11, except that the first barrier layer 41 includes two layers of different materials (e.g., SiN and SiON), for example.

Referring again to FIG. 11, in some embodiments, a silicon nitride material for a first sub-layer 42a of the second barrier layer 42 and a silicon oxynitride material for the second sub-layer 42b of the second barrier layer 42 can be deposited using a same chamber of a given tool. This can make alternating between SiN deposition and SiON deposition during the formation of the first barrier layer 41 and/or the second barrier layer 42 relatively easy for forming a multilayer structure of differing material composition for the first barrier layer 41 and/or the second barrier layer 42.

In some embodiments, the first barrier layer 41 and/or the second barrier layer 42 can be SiN. In some embodiments, the first barrier layer 41 and/or the second barrier layer 42 can be SiON. In some embodiments using SiON as or included in a barrier layer (41 and/or 42), the nitrogen content can be varied during the deposition (e.g., during PECVD) so that the resulting SiON is more nitrogen rich and less oxygen rich. In some embodiments, the first barrier layer 41 can include multiple layers with a SiN as the upper-most layer at the interface with the metal mask layer 22 (i.e., directly contacting) to provide stronger barrier protection against oxygen migrating into the metal mask layer 22 from the underlying substrate 26. Similarly, in some embodiments, the second barrier layer 42 can include multiple layers with a SiN as the lower-most layer at the interface with the metal mask layer 22 (i.e., directly contacting) to provide stronger barrier protection against oxygen migrating into the metal mask layer 22 from the first mask layer 30.

Because SiN and SiON can be formed in a same chamber using a same tool, when depositing the second barrier layer 42, the deposition may begin with precursors (e.g., using PECVD) that result in forming a layer or layers of SiN. And as the same PECVD deposition progresses, amounts and/or flow rates of precursors that include oxygen or that result in the formation of SiON can be gradually or step-wise increased (after some SiN has been deposited to a sufficient thickness, e.g., at least 5 nm) such that the SiON formed initially has higher concentrations/ratios of nitrogen relative to oxygen. Subsequently, as the amount or flow rate of oxygen containing precursors are increased, the amount or flow rate of nitrogen containing precursors can be decreased such that subsequently formed layers or sub-layers of SiON will have relatively higher concentrations of oxygen relative to nitrogen. In some embodiments, the first dielectric layer 51 and the second barrier layer 42 can be deposited using a same chamber of a given tool. Accordingly, this progression could continue with reduction of nitrogen-containing precursors and/or introduction of TEOS such that there becomes a gradual or continuous transition to forming SiO₂ from TEOS until there is little or no nitrogen present. Such transitions and use of a same chamber and same tool can increase process efficiency in depositing multiple layers and/or sub-layers of the first mask layer 30 of different material compositions, starting with a relatively higher concentration of nitrogen for improving the barrier layer characteristics for protecting the metal mask layer 22 from oxidation during the formation of the first mask layer 30. In some embodiments, the first dielectric layer 51 and the second barrier layer 42 can be deposited in different chambers and/or using different tools. In some embodiments, gases introduced to deposit SiON can be silane (SiH₄), ammonia (NH₃), or nitrogen (N₂), with oxygen (O₂), whereas SiO₂ deposition that uses TEOS as a precursor can use TEOS and O₂ or ozone (O₃), for example.

For example, the second barrier layer 42 can be a very thin layer of SiN (e.g., 5-10 nm) followed by SiON formation with progressively more oxygen content and then transitioning to a SiO₂ layer (by gradually introducing TEOS flow and reduce nitrogen-containing flow) for the first dielectric layer 51. In some embodiments, it can be desirable to minimize the nitrogen to reduce the redeposition at the top surface of the first mask layer 30 (likely caused by the plasma environment above the wafer, and/or gases used during plasma etch). Thus, in some embodiments, the SiN layer of the second barrier layer 42 can be minimal to provide a sufficient barrier layer to prevent the oxidation of the metal mask layer 22 during the deposition of the layers of the first mask layer 30. And then, a more oxygen rich layer (e.g., using TEOS for the first dielectric layer 51) can provide better etch selectivity when etching the holes 20 into the metal mask layer 22 using the first mask layer 30 as a pattern, for example.

In some embodiments, the first barrier layer 41 and/or the second barrier layer 42 can be deposited in a way to form a tensile or compressively strained layer, which can be helpful for managing thermal expansions and thermal stresses in the process integration.

As described above, a thickness ratio between the second barrier layer 42 and the first dielectric layer 51 can be varied. Similarly, a thickness of a first sub-layer 42a, a second sub-layer 42b, and the first dielectric layer 51 can be varied to provide optimal etching of the holes 20 through the metal mask layer 22. For example, for some material compositions of the metal mask layer 22 and for some etch/passivation chemistries for forming the holes 20 in the metal mask layer 22, having the SiN layer too thick can result in some redeposition of etched-away materials at the top of the holes (e.g., forming WOₓN_{y}) during etching/passivation operations that include oxygen. Also, the etch selectivity of SiO₂ can be greater than that of SiN for etching/passivation operations that include oxygen. Thus, for such process flows, it can be desirable to keep the thickness of the SiN for the second barrier layer 42 much thinner than the thickness of the SiO₂ of the first dielectric layer 51, for example. On the other hand, use of SiN and/or SiON (or materials including nitrogen) in the first mask layer 30 can reduce scalloping and reduce sidewall roughness for the holes 20 for some etch/passivation chemistries for etching the metal mask layer 22 (dependent also on the material composition of the metal mask layer 22). The selection of the thickness of the second barrier layer 42, and whether it is SiN or SiN plus SiON, can be dependent on the etch chemistry and passivation chemistry used for etching the holes 20 into the metal mask layer 22, particularly the amount of oxygen used during the etching (e.g., volatile byproducts of WOₓCl_{y} can further react with oxygen radicals to redeposit on the SiN surfaces, which can be redeposited at the top of the first mask layer 30). Thus, there are several parameters and factors that one can take into consideration for selecting the thicknesses of the second barrier layer 42 (or the first sub-layer 42a and second sub-layer 42b) and the first dielectric layer 51 for optimizing the performance of the first mask layer 30 for consistently and uniformly forming holes 20 in the metal mask layer 22. By combining the use of SiO₂ in the first dielectric layer 51 and SiN in the second barrier layer 42, for example, an embodiment of the present disclosure can provide benefits of higher etch selectivity provided by the SiO₂ while also providing the barrier layer protection of the SiN therebetween.

Similarly, having nitrogen in the first barrier layer 41 can create some nitridation of the tungsten material in the metal mask layer 22 near the bottom of the holes 20, which can contribute to more of a tapered profile (i.e., less of a desired straight profile for sidewalls of the hole bottoms) at the bottom of the metal mask layer 22 (i.e., at the foot of the metal hard mask). Using SiON in the first barrier layer 41 can cause some partial oxidizing of the metal at the bottom of the metal mask layer 22 to help open up the bottom of the holes 20 in the metal mask layer 22 (see e.g., FIG. 8 for illustration of a hole 20 in the metal mask layer 22). Accordingly, selection of material(s) and/or sub-layer structure(s) of the first barrier layer 41 can affect the uniformity and critical dimensions at the bottom of the holes 20 formed in the metal mask layer 22, which can be dependent on the materials of the metal mask layer 22 and the first barrier layer 41, as well as the etch/passivation chemistries used for forming the holes 20 in the metal mask layer 22. The overall thickness of the first barrier layer 41 can depend on the process flow integration. Thus, there are several parameters and factors that one can take into consideration for selecting the material(s) and/or sub-layer structure(s) of the first barrier layer 41 for an optimal process integration.

Because the first barrier layer 41 is located below the metal mask layer 22, the first barrier layer 41 can be considered part of the substrate 26 for purposes of discussion for some embodiments herein, without departing from the scopes of the present disclosure. One of the main functions of the first barrier layer 41 can be to separate the metal mask layer 22 from other portions of the substrate 26 that include oxygen to prevent, hinder, or reduce migration of oxygen from the substrate 26 into the metal mask layer 22. Another potential function of the first barrier layer 41 can be acting as an etch stop layer in the case where there is etch selectivity of the metal mask layer 22 relative to the first barrier layer 41. After the holes 20 are extending into the substrate 26 during subsequent processing steps, part or all of the first barrier layer 41 may be removed during an operation of removing the metal mask layer 22 (and again the first barrier layer 41 can provide some properties of being an etch stop layer during removal of the metal mask layer 22). Alternatively, part or all of the first barrier layer 41 may remain after the removal the metal mask layer 22 during some or all of subsequent processing operations (e.g., remnants of the first barrier layer 41 can be removed later or can remain in the final semiconductor device).

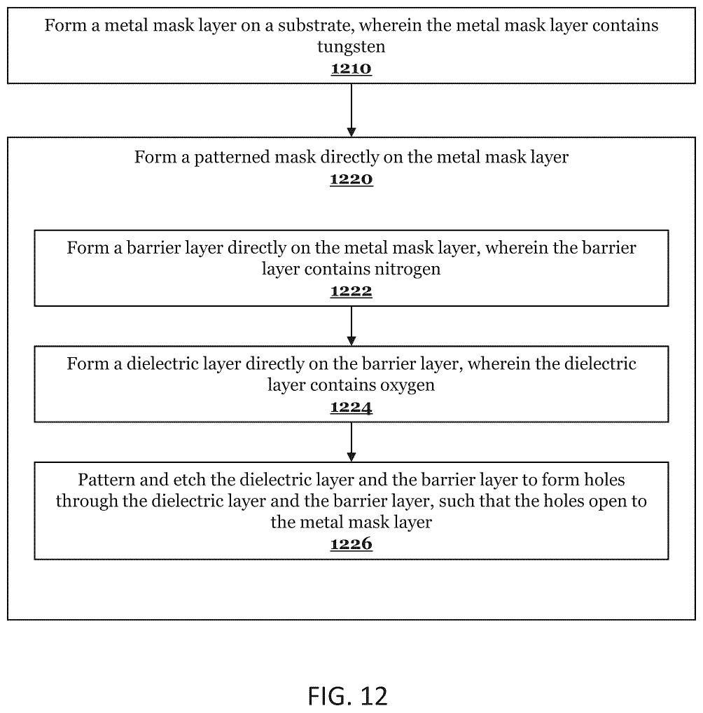

FIG. 12 illustrates a flow chart implementing a mask structure in accordance with an embodiment of the present disclosure. In an embodiment, a method for making a semiconductor device includes forming a metal mask layer on a substrate, wherein the metal mask layer contains tungsten (e.g., tungsten with silicon and/or nitrogen) (box 1210). The method includes forming a patterned mask directly on the metal mask layer (box 1220). The forming of the patterned mask includes forming a barrier layer directly on the metal mask layer, where the barrier layer contains nitrogen (box 1222). The forming of the patterned mask includes forming a dielectric layer directly on the barrier layer, where the dielectric layer contains oxygen (box 1224). The forming of the patterned mask includes patterning and etching of the dielectric layer and the barrier layer to form holes through the dielectric layer and the barrier layer, such that the holes open to the metal mask layer (box 1226).

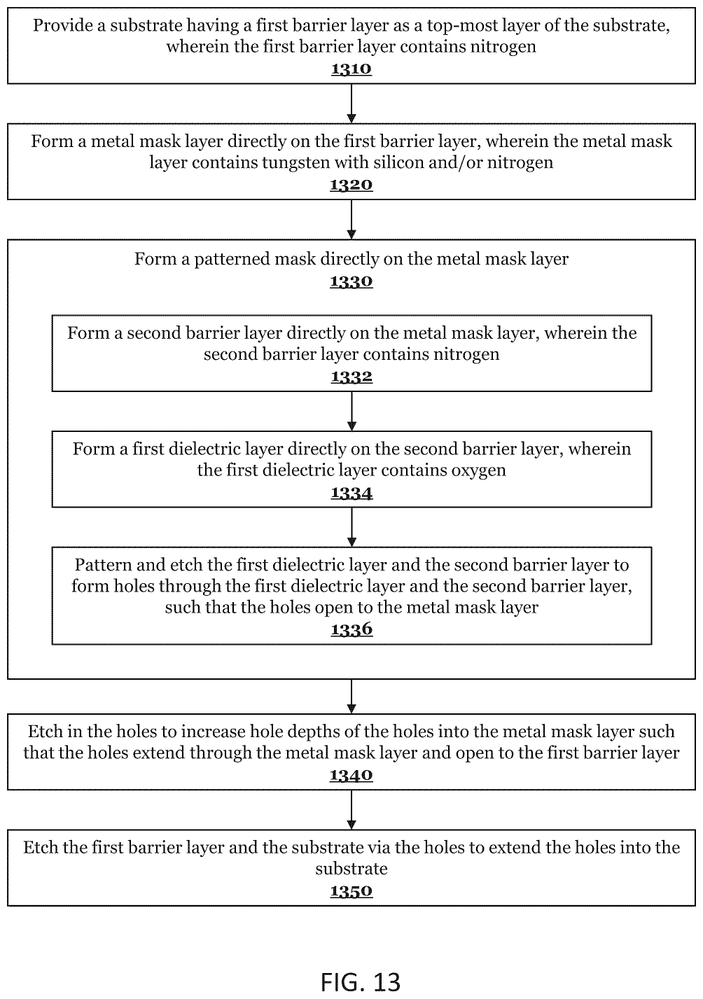

FIG. 13 illustrates a flow chart implementing a mask structure in accordance with an embodiment of the present disclosure. In an embodiment, a method for making a semiconductor device includes providing a substrate having a first barrier layer as a top-most layer of the substrate, where the first barrier layer contains nitrogen (box 1310). The method includes forming a metal mask layer directly on the first barrier layer, wherein the metal mask layer contains tungsten with silicon and/or nitrogen (box 1320). The method includes forming a patterned mask directly on the metal mask layer (box 1330). The forming of the patterned mask includes forming a second barrier layer directly on the metal mask layer, where the second barrier layer contains nitrogen (box 1332). The forming of the patterned mask includes forming a first dielectric layer directly on the second barrier layer, where the first dielectric layer contains oxygen (box 1334). The forming of the patterned mask includes patterning and etching the first dielectric layer and the second barrier layer to form holes through the first dielectric layer and the second barrier layer, such that the holes open to the metal mask layer (box 1336). The method includes etching in the holes to increase hole depths of the holes into the metal mask layer such that the holes extend through the metal mask layer and open to the first barrier layer (e.g., etching contact holes into the metal mask layer such that the contacts extend through the metal mask and open to the first barrier layer) (box 1340). The method includes etching the first barrier layer and the substrate via the holes to extend the holes into the substrate (box 1350). In some embodiments, the method can include removing the first dielectric layer and the second barrier layer, before or during the etching the first barrier layer and the substrate via the holes to extend the holes into the substrate.

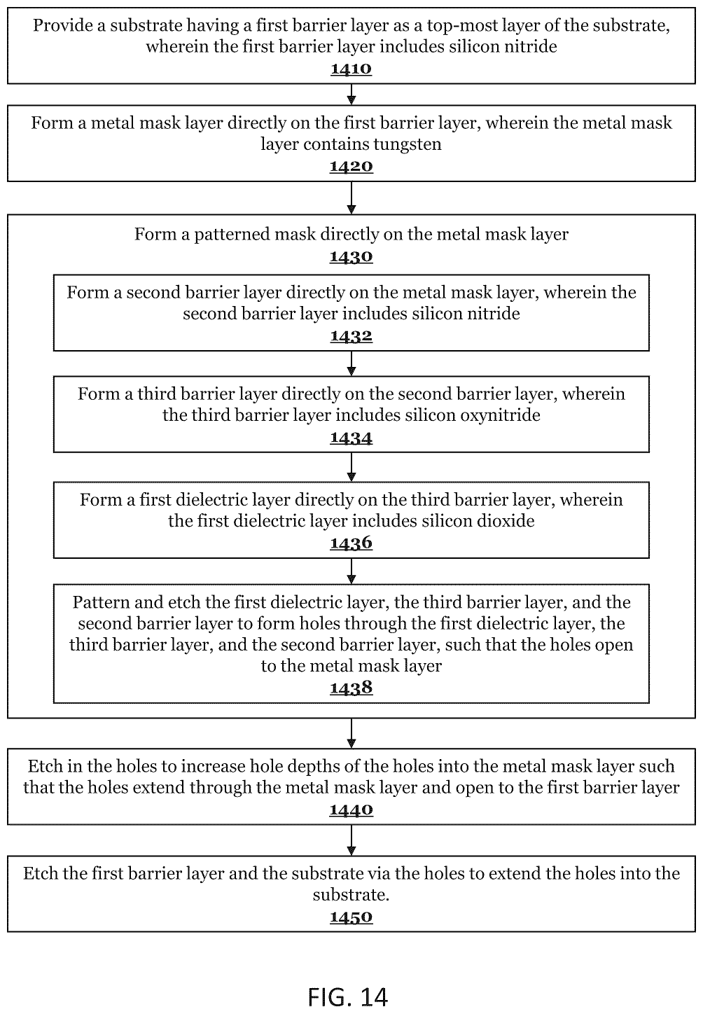

FIG. 14 illustrates a flow chart implementing a mask structure in accordance with an embodiment of the present disclosure. In an embodiment, a method for making a semiconductor device includes providing a substrate having a first barrier layer as a top-most layer of the substrate, wherein the first barrier layer includes silicon nitride (box 1410). The method includes forming a metal mask layer directly on the first barrier layer, wherein the metal mask layer contains tungsten (e.g., tungsten with silicon and/or nitrogen) (box 1420). The method includes forming a patterned mask directly on the metal mask layer (box 1430). The forming of the patterned mask includes forming a second barrier layer directly on the metal mask layer, where the second barrier layer includes silicon nitride (box 1432). The forming of the patterned mask includes forming a third barrier layer directly on the second barrier layer, where the third barrier layer includes silicon oxynitride (box 1434). The forming of the patterned mask includes forming a first dielectric layer directly on the third barrier layer, wherein the first dielectric layer includes silicon dioxide (box 1436). The forming of the patterned mask includes patterning and etching the first dielectric layer, the third barrier layer, and the second barrier layer to form holes through the first dielectric layer, the third barrier layer, and the second barrier layer, such that the holes open to the metal mask layer (box 1438). The method includes etching in the holes to increase hole depths of the holes into the metal mask layer such that the holes extend through the metal mask layer and open to the first barrier layer (box 1440). The method includes etching the first barrier layer and the substrate via the holes to extend the holes into the substrate (box 1450). In some embodiments, the method can include removing the first dielectric layer, the third barrier layer, and the second barrier layer, before or during the etching the first barrier layer and the substrate via the holes to extend the holes into the substrate.

The embodiments described in FIGS. 12-14 may be implemented as further described using FIGS. 1-11.

More example embodiments of the present disclosure are summarized here. Other embodiments can also be understood from the entirety of the specification as well as the claims filed herein.

### Example 1

A method for forming a semiconductor device including: forming a metal mask layer on a substrate, where the metal mask layer contains tungsten; and forming a patterned mask directly on the metal mask layer, where the forming of the patterned mask includes forming a barrier layer directly on the metal mask layer, where the barrier layer contains nitrogen, forming a dielectric layer directly on the barrier layer, where the dielectric layer contains oxygen, and patterning and etching the dielectric layer and the barrier layer to form holes through the dielectric layer and the barrier layer, such that the holes open to the metal mask layer.

### Example 2

The method of example 1, where the barrier layer includes a silicon nitride layer, and where the dielectric layer includes a silicon dioxide layer.

### Example 3

The method of one of examples 1 or 2, where the barrier layer includes a silicon nitride layer and a silicon oxynitride layer, where the silicon nitride layer is between the silicon oxynitride layer and the metal mask layer.

### Example 4

The method of one of examples 1 to 3, where the metal mask layer also contains silicon.

### Example 5

The method of one of examples 1 to 4, where the metal mask layer also contains nitrogen.

### Example 6

The method of one of examples 1 to 5, where the metal mask layer contains 59-63% tungsten, 21-25% silicon, and 14-18% nitrogen.

### Example 7

The method of one of examples 1 to 6, where the metal mask layer contains 61-65% tungsten, 9-13% silicon, and 23-27% nitrogen.

### Example 8

The method of one of examples 1 to 7, where the forming of the metal mask layer includes physical vapor deposition.

### Example 9

The method of one of examples 1 to 8, where the substrate includes a substrate barrier layer as a top-most layer of the substrate, where the forming of the metal mask layer is directly on the substrate barrier layer, and where the substrate barrier layer contains nitrogen.

### Example 10

A method for forming a semiconductor device including: providing a substrate having a first barrier layer as a top-most layer of the substrate, where the first barrier layer contains nitrogen; forming a metal mask layer directly on the first barrier layer, where the metal mask layer contains tungsten and where the metal mask layer contains silicon, nitrogen, or a combination of silicon and nitrogen; and forming a patterned mask directly on the metal mask layer, where the forming of the patterned mask includes forming a second barrier layer directly on the metal mask layer, where the second barrier layer contains nitrogen, forming a first dielectric layer directly on the second barrier layer, where the first dielectric layer contains oxygen, and patterning and etching the first dielectric layer and the second barrier layer to form holes through the first dielectric layer and the second barrier layer, such that the holes open to the metal mask layer.

### Example 11

The method of example 10, further including: etching in the holes to increase hole depths of the holes into the metal mask layer such that the holes extend through the metal mask layer and open to the first barrier layer; and etching the first barrier layer and the substrate via the holes to extend the holes into the substrate.

### Example 12

The method of one of examples 10 or 11, further including removing the first dielectric layer and the second barrier layer.

### Example 13

The method of one of examples 10 to 12, where the second barrier layer includes a silicon nitride layer and a silicon oxynitride layer, and where the silicon nitride layer is between the silicon oxynitride layer and the metal mask layer.

### Example 14

The method of one of examples 10 to 13, where the first barrier layer includes a first silicon nitride layer, where the second barrier layer include a second silicon nitride layer, and where the first dielectric layer includes a first silicon dioxide layer.

### Example 15

The method of one of examples 10 to 14, where the second barrier layer further includes a first silicon oxynitride layer, where the second silicon nitride layer is between the first silicon oxynitride layer and the metal mask layer.

### Example 16

The method of one of examples 10 to 15, where the first barrier layer includes a silicon oxynitride layer.

### Example 17

A method for forming a semiconductor device including: providing a substrate having a first barrier layer as a top-most layer of the substrate, where the first barrier layer includes silicon nitride; forming a metal mask layer directly on the first barrier layer, where the metal mask layer contains tungsten; and forming a patterned mask directly on the metal mask layer, where the forming of the patterned mask includes forming a second barrier layer directly on the metal mask layer, where the second barrier layer includes silicon nitride, forming a third barrier layer directly on the second barrier layer, where the third barrier layer includes silicon oxynitride, forming a first dielectric layer directly on the third barrier layer, where the first dielectric layer includes silicon dioxide, and patterning and etching the first dielectric layer, the third barrier layer, and the second barrier layer to form holes through the first dielectric layer, the third barrier layer, and the second barrier layer, such that the holes open to the metal mask layer.

### Example 18

The method of example 17, where the metal mask layer also contains silicon.

### Example 19

The method of one of examples 17 or 18, where the metal mask layer also contains nitrogen.

### Example 20

The method of one of examples 17 to 19, further including: etching in the holes to increase hole depths of the holes into the metal mask layer such that the holes extend through the metal mask layer and open to the first barrier layer; and etching the first barrier layer and the substrate via the holes to extend the holes into the substrate.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for forming a semiconductor device, the method comprising:
forming a metal mask layer on a substrate, wherein the metal mask layer contains tungsten; and
forming a patterned mask directly on the metal mask layer, wherein the forming of the patterned mask includes:
forming a barrier layer directly on the metal mask layer, wherein the barrier layer contains nitrogen,
forming a dielectric layer directly on the barrier layer, wherein the dielectric layer contains oxygen, and
patterning and etching the dielectric layer and the barrier layer to form holes through the dielectric layer and the barrier layer, such that the holes open to the metal mask layer.

2. The method of claim 1, wherein the barrier layer comprises a silicon nitride layer, and wherein the dielectric layer comprises a silicon dioxide layer.

3. The method of claim 1, wherein the barrier layer comprises a silicon nitride layer and a silicon oxynitride layer, wherein the silicon nitride layer is between the silicon oxynitride layer and the metal mask layer.

4. The method of claim 1, wherein the metal mask layer also contains silicon.

5. The method of claim 4, wherein the metal mask layer also contains nitrogen.

6. The method of claim 5, wherein the metal mask layer contains 59-63% tungsten, 21-25% silicon, and 14-18% nitrogen.

7. The method of claim 5, wherein the metal mask layer contains 61-65% tungsten, 9-13% silicon, and 23-27% nitrogen.

8. The method of claim 1, wherein the forming of the metal mask layer includes physical vapor deposition.

9. The method of claim 1, wherein the substrate comprises a substrate barrier layer as a top-most layer of the substrate, wherein the forming of the metal mask layer is directly on the substrate barrier layer, and wherein the substrate barrier layer contains nitrogen.

10. A method for forming a semiconductor device, the method comprising:
providing a substrate having a first barrier layer as a top-most layer of the substrate, wherein the first barrier layer contains nitrogen;
forming a metal mask layer directly on the first barrier layer, wherein the metal mask layer contains tungsten and wherein the metal mask layer contains silicon, nitrogen, or a combination of silicon and nitrogen; and
forming a patterned mask directly on the metal mask layer, wherein the forming of the patterned mask includes:
forming a second barrier layer directly on the metal mask layer, wherein the second barrier layer contains nitrogen,
forming a first dielectric layer directly on the second barrier layer, wherein the first dielectric layer contains oxygen, and
patterning and etching the first dielectric layer and the second barrier layer to form holes through the first dielectric layer and the second barrier layer, such that the holes open to the metal mask layer.

11. The method of claim 10, further comprising:
etching in the holes to increase hole depths of the holes into the metal mask layer such that the holes extend through the metal mask layer and open to the first barrier layer; and
etching the first barrier layer and the substrate via the holes to extend the holes into the substrate.

12. The method of claim 11, further comprising removing the first dielectric layer and the second barrier layer.

13. The method of claim 10, wherein the second barrier layer comprises a silicon nitride layer and a silicon oxynitride layer, and wherein the silicon nitride layer is between the silicon oxynitride layer and the metal mask layer.

14. The method of claim 10, wherein the first barrier layer comprises a first silicon nitride layer, wherein the second barrier layer comprise a second silicon nitride layer, and wherein the first dielectric layer comprises a first silicon dioxide layer.

15. The method of claim 14, wherein the second barrier layer further comprises a first silicon oxynitride layer, wherein the second silicon nitride layer is between the first silicon oxynitride layer and the metal mask layer.

16. The method of claim 10, wherein the first barrier layer comprises a silicon oxynitride layer.

17. A method for forming a semiconductor device, the method comprising:
providing a substrate having a first barrier layer as a top-most layer of the substrate, wherein the first barrier layer includes silicon nitride;
forming a metal mask layer directly on the first barrier layer, wherein the metal mask layer contains tungsten; and
forming a patterned mask directly on the metal mask layer, wherein the forming of the patterned mask includes:
forming a second barrier layer directly on the metal mask layer, wherein the second barrier layer includes silicon nitride,
forming a third barrier layer directly on the second barrier layer, wherein the third barrier layer includes silicon oxynitride,
forming a first dielectric layer directly on the third barrier layer, wherein the first dielectric layer includes silicon dioxide, and
patterning and etching the first dielectric layer, the third barrier layer, and the second barrier layer to form holes through the first dielectric layer, the third barrier layer, and the second barrier layer, such that the holes open to the metal mask layer.

18. The method of claim 17, wherein the metal mask layer also contains silicon.

19. The method of claim 18, wherein the metal mask layer also contains nitrogen.

20. The method of claim 17, further comprising:
etching in the holes to increase hole depths of the holes into the metal mask layer such that the holes extend through the metal mask layer and open to the first barrier layer; and
etching the first barrier layer and the substrate via the holes to extend the holes into the substrate.
